(19) United States
(12) Patent Application Publication
(10) Pub. No.: US 2024/0379719 A1
(43) Pub. Date: Nov. 14, 2024

(54) IMAGE SENSOR AND METHOD OF MANUFACTURING THE SAME

(71) Applicant: Samsung Electronics Co., Ltd., Suwon-si (KR)

(72) Inventor: Eun Sub Shim, Suwon-si (KR)

(21) Appl. No.: 18/651,993

(22) Filed: May 1, 2024

(30) Foreign Application Priority Data
May 8, 2023 (KR) 10-2023-0059259

(51) Int. Cl. H01L 27/146

(52) U.S. Cl. CPC H01L 27/14636; H01L 27/14605; H01L 27/1461

(57) ABSTRACT

The present disclosure relates to an image sensor, and the image sensor of the present disclosure may include a plurality of pixels, each of which includes a photovoltaic device configured to convert incident light into charge, and a capacitor configured to store the charge, the capacitor of each of the plurality of pixels may include a first electrode and a second electrode that overlap each other, and a dielectric layer that is between the first electrode and the second electrode, the plurality of pixels may include a first pixel and a second pixel adjacent to each other, and the second electrode of the first pixel and the second electrode of the second pixel may be integral with each other.

### CROSS-REFERENCE TO RELATED APPLICATION

This application claims priority to and the benefit of Korean Patent Application No. 10-2023-0059259 filed in the Korean Intellectual Property Office on May 8, 2023, the entire contents of which are incorporated herein by reference.

### BACKGROUND

The present disclosure relates to an image sensor.

CMOS image sensors are solid-state image sensing devices using complementary metal-oxide semiconductors (CMOSs). As compared to charge-coupled device (CCD) image sensors with high-voltage analog circuits, CMOS image sensors have the advantages of low manufacturing costs and low power consumption due to the small sizes of elements, so CMOS image sensors are mainly mounted in home appliances including portable devices such as smart phones, digital cameras, etc.

CMOS image sensors include pixel arrays. A pixel array consists of a plurality of pixels, each of which may include a photovoltaic device and a floating diffusion (FD) zone. The photovoltaic device generates an electrical signal that varies depending on the amount of incident light, and the generated electrical signal is output through the FD zone.

Recently, image sensors capable of efficiently operating in each of low-light environments and high-light environments have been researched. For example, such image sensors may include two floating diffusion zones FD1 and FD2. Further, in order to improve the capacitance of the floating diffusion zones FD1 and FD2, at least one of the two floating diffusion zones FD1 and FD2 may be implemented as a metal-insulator-metal (MIM) capacitor.

However, wiring for MIM capacitors requires a wide area, and thus it is difficult to form such wiring in an image sensor which consists of miniaturized pixels for providing high resolution.

### SUMMARY

The present disclosure aims to provide an image sensor and a method of manufacturing the same, in which it is possible to efficiently configure wiring for MIM capacitors which form floating diffusion zones.

An image sensor according to aspects of the present disclosure includes a plurality of pixels, each of which includes a photovoltaic device configured to convert incident light into charge, and a capacitor configured to store the charge, the capacitor of each of the plurality of pixels may include a first electrode and a second electrode that overlap each other, and a dielectric layer that is between the first electrode and the second electrode, the plurality of pixels may include a first pixel and a second pixel adjacent to each other, and the second electrode of the first pixel and the second electrode of the second pixel may be integral with each other.

An image sensor according to aspects of the present disclosure includes a plurality of pixels, each of which includes a photovoltaic device configured to convert incident light into charge, a first floating diffusion zone and a second floating diffusion zone that are coupled to the photovoltaic device, a transfer transistor that is coupled between the photovoltaic device and the first floating diffusion zone, and a dual conversion gain transistor that is coupled between the first floating diffusion zone and the second floating diffusion zone, the second floating diffusion zone may include a capacitor, the capacitor may include a first electrode and a second electrode that overlap each other, and a dielectric layer that is between the first electrode and the second electrode, the plurality of pixels may include a first pixel and a second pixel adjacent to each other, and the second electrode of the first pixel and the second electrode of the second pixel may be integral with each other.

An image sensor according to aspects of the present disclosure includes a plurality of pixels, each of which includes a light transmission layer, a photoelectric conversion layer configured to convert light passing through the light transmission layer into an electrical signal, a transfer transistor that is coupled to the photoelectric conversion layer, a first floating diffusion zone and a dual conversion gain transistor that are coupled to the transfer transistor, and a capacitor that is coupled to the dual conversion gain transistor, the capacitor may include a first electrode and a second electrode that overlap each other, and a dielectric layer that is between the first electrode and the second electrode, the plurality of pixels may include a first pixel and a second pixel adjacent to each other, and the second electrode of the first pixel and the second electrode of the second pixel may be integral with each other.

According to the present disclosure, it is possible to provide an image sensor capable of efficiently operating in each of low-light environments and high-light environments even when miniaturized pixels are used to provide high resolution.

According to the present disclosure, some electrodes of MIM capacitors included in a plurality of pixels arranged adjacent to each other may be shared by the MIM capacitors, whereby it is possible to efficiently configure wiring. As a result, it is possible to increase the areas of MIM capacitors, thereby improving their capacitance.

### BRIEF DESCRIPTION OF THE DRAWINGS

FIG. 1 is a block diagram schematically illustrating an image sensor according to some embodiments.

FIG. 2 is a circuit diagram for explaining the structure of a pixel PX included in the pixel array of FIG. 1.

FIG. 3 is a plan view for explaining the structure of a pixel PX included in the pixel array of FIG. 1.

FIG. 4 is a cross-sectional view taken along line A-A′ of FIG. 3.

FIG. 5 is an enlarged plan view illustrating MIM capacitors which constitute second floating diffusion zones in region M of FIG. 1.

FIG. 6 is a plan view illustrating first electrodes of the MIM capacitors shown in FIG. 5.

FIG. 7 is a plan view illustrating a common electrode corresponding to the second electrodes of the MIM capacitors shown in FIG. 5.

FIG. 8 is a cross-sectional view taken along line B-B′ of FIG. 5.

FIG. 9 is a cross-sectional view taken along line C-C′ of FIG. 5.

FIG. 10 is a cross-sectional view taken along line D-D′ of FIG. 5.

FIG. 11 is an enlarged plan view illustrating MIM capacitors which constitute second floating diffusion zones according to some embodiments.

FIG. 12 and FIG. 13 are enlarged plan views illustrating MIM capacitors which constitute second floating diffusion zones according to some embodiments.

FIG. 14 is an enlarged first cross-sectional view illustrating a plurality of MIM capacitors which constitute second floating diffusion zones according to some embodiments.

FIG. 15 is an enlarged second cross-sectional view illustrating a plurality of MIM capacitors which constitute second floating diffusion zones according to some embodiments.

FIGS. 16 to 18 are views illustrating examples of electronic devices to which an image sensor according to some embodiments has been applied.

### DETAILED DESCRIPTION

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings is shown for understanding and ease of description, but the present disclosure is not limited thereto. In the drawings, the thickness of layers, films, panels, regions, etc., may be exaggerated for clarity. In the drawings, for understanding and ease of description, the thickness of some layers and areas may be exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element may be located above or below the reference portion, and it does not necessarily mean that the element is located “above” or “on” in a direction opposite to gravity.

In addition, unless explicitly described to the contrary, it will be understood that the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

Further, in the entire specification, when referring to “on a plane”, it means when a target part is viewed from above, and when referring to “on a cross-section”, it means when the cross-section obtained by cutting a target part vertically is viewed from the side.

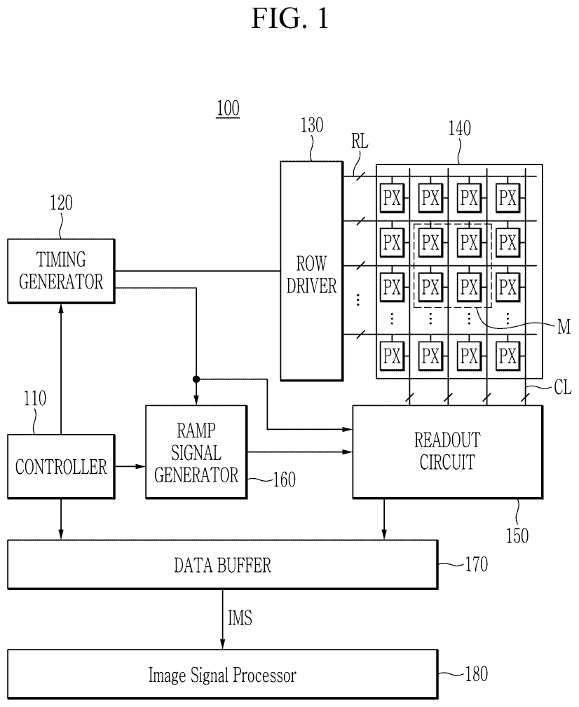

FIG. 1 is a block diagram schematically illustrating an image sensor according to some embodiments.

Referring to FIG. 1, an image sensor 100 may include a pixel array 140 and a logic circuit.

The image sensor 100 may generate image signals by converting light received from the outside into electrical signals. For example, the image sensor 100 may transmit the generated image signals to an image signal processor 180 to be described below.

The image sensor 100 may be mounted in an electronic device which has an image or light sensing function. For example, the image sensor 100 may be mounted in electronic devices such as cameras, smart phones, wearable devices, IoT (Internet of Things) devices, home appliances, table PCs (personal computers), navigation devices, drones, advanced drivers assistance systems (ADASs), etc. Also, the image sensor 100 may be mounted in electronic devices which are incorporated as components in vehicles, furniture, manufacturing equipment, doors, various measuring devices, etc.

The pixel array 140 may include a plurality of pixels PX1 to PXn, a plurality of row lines RL1 to RLn, and a plurality of column lines CL1 to CLn. For example, the row lines RL and the column lines CL may be coupled to the pixels PX, respectively.

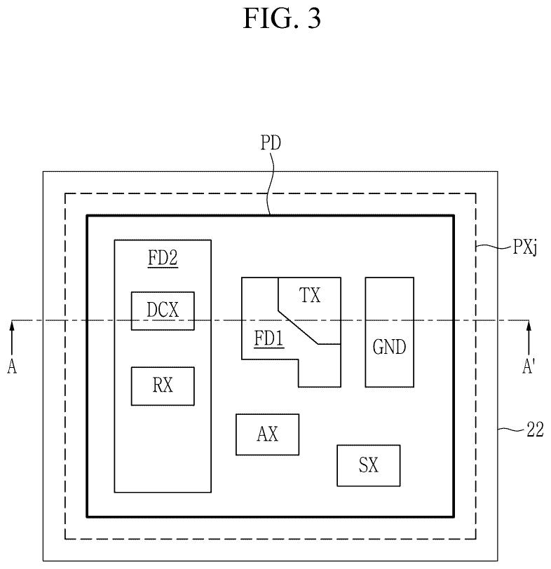

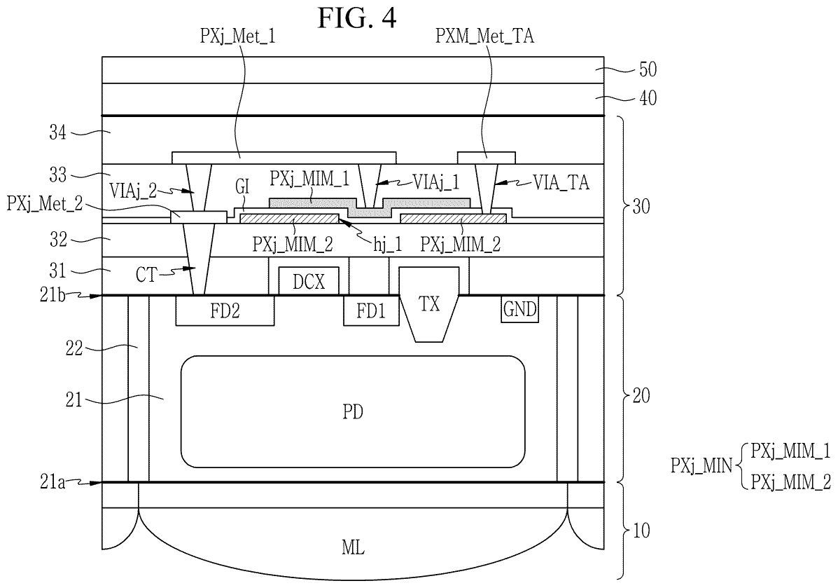

The pixels PX may include photovoltaic devices. The photovoltaic devices may detect incident light and generate electrical signals (i.e., charge) corresponding to the amounts of light. Here, the electrical signals may correspond to analog pixel signals. As an example, the photovoltaic devices (corresponding to the reference symbol “PD” in FIG. 3 and FIG. 4) may be photodiodes, pinned diodes, etc. As another example, the photovoltaic devices may be single-photon avalanche diodes (SPADs) which are applied to 3D sensor pixels.

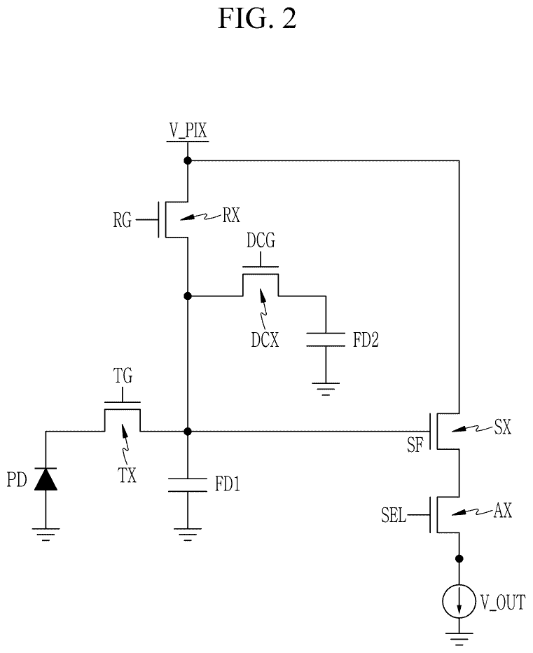

The levels of analog pixel signals which the photovoltaic devices output may be proportional to the amounts of charge which are output from the photovoltaic devices. In other words, the levels of analog pixel signals may be determined depending on the amount of light which enters the pixel array 140. Various components which constitute pixels PX will be described below in detail with reference to FIG. 2 and FIG. 3.

The plurality of row lines RL1 to RLn may be electrically coupled to the plurality of pixels PX1 to PXn. For example, control signals which are output from a row driver 130 to the row lines RL may be transmitted to the gates of the transistors of the plurality of pixels PX1 to PXn coupled to the corresponding row lines RL.

The plurality of column lines CL1 to CLn may be electrically coupled to the plurality of pixels PX1 to PXn. Specifically, a column line CL may be located so as to intersect predetermined row lines RL. A plurality of pixel signals which are output from the plurality of pixels PX1 to PXn may be transmitted to a readout circuit 150 through the plurality of column lines CL1 to CLn.

In some embodiments, the plurality of pixels PX1 to PXn may be arranged along a plurality of rows and a plurality of columns, and each pixel PX may output one analog pixel signal. However, the present disclosure is not limited thereto, and various modifications can be made. For example, the plurality of pixels PX1 to PXn may be grouped in the form of a matrix having a plurality of columns and a plurality of rows, thereby forming one unit pixel group. One unit pixel group may include a plurality of pixels PX1 to PXn arranged in the form of a 2-by-2 matrix, and one unit pixel group may output one analog pixel signal.

The logic circuit is a circuit for controlling the pixel array 140. For example, the logic circuit may include a controller 110, a timing generator 120, the row driver 130, the readout circuit 150, a ramp signal generator 160, a data buffer 170, etc. As another example, the logic circuit may further include the image signal processor 180. In some embodiments, the image signal processor 180 may be located outside the image sensor 100 (i.e., located external to the image sensor 100).

The controller 110 may control the operation timings of the timing generator 120, the row driver 130, the readout circuit 150, the ramp signal generator 160, and the data buffer 170, using control signals.

In some embodiments, the controller 110 may receive a mode signal indicating an imaging mode from an application processor, and may generally control the image sensor 100 on the basis of the received mode signal. For example, the application processor may determine the imaging mode of the image sensor 100 according to various scenarios such as the intensity of illumination in the imaging environment, the user's resolution setting, a sensed or learned state, etc., and may provide a mode signal indicating the determined result to the controller 110.

The controller 110 may control the plurality of pixels PX1 to PXn according to the imaging mode, such that the pixels output pixel signals. The pixel array 140 may output the pixel signals of the plurality of pixels PX1 to PXn or the pixel signals of some of the plurality of pixels PX1 to PXn. The readout circuit 150 may sample and process the pixel signals received from the pixel array 140.

The timing generator 120 may generate a signal to be a reference for the operation timings of the components of the image sensor 100. The timing generator 120 may control the timings of the row driver 130, the readout circuit 150, and the ramp signal generator 160. The timing generator 120 may provide control signals to control the timings of the row driver 130, the readout circuit 150, and the ramp signal generator 160.

The row driver 130 may generate a control signal for driving the pixel array 140, in response to a control signal of the timing generator 120, and may provide the control signal to a plurality of pixels PX of the pixel array 140 through a plurality of row lines RL.

In some embodiments, the row driver 130 may control the pixels PX in units of a row line, such that the pixels detect incident light. Each row line unit may include at least one row line RL. For example, the row driver 130 may generate a transmission control signal for controlling transfer transistors, a reset control signal for controlling reset transistors, a selection control signal for controlling selected transistors, etc., and may provide the signals to the pixel array 140.

The readout circuit 150 may convert the pixel signals (or electrical signals) received from pixels PX coupled to a selected row line RL among the plurality of pixels PX1 to PXn into pixel values indicating light amounts, in response to a control signal from the timing generator 120.

The readout circuit 150 may convert pixel signals output through corresponding column lines CL into pixel values. For example, the readout circuit 150 may convert pixel signals into pixel values by comparing the pixel signals with ramp signals. Pixel values may be image data items, each of which has a plurality of bits. Specifically, the readout circuit 150 may include a selector, a plurality of comparators, a plurality of counter circuits, etc.

The ramp signal generator 160 may generate a reference signal, and transmit the reference signal to the readout circuit 150. The ramp signal generator 160 may include current sources, resistors, and capacitors. The ramp signal generator 160 may adjust ramp voltage which is voltage to be applied to a ramp resistor by adjusting the current magnitude of a variable current source or the resistance value of a variable resistor. In this way, the ramp signal generator 160 may generate a plurality of ramp signals which fall or rise at slopes determined depending on the current magnitudes of variable current sources or the resistance values of variable resistors.

The data buffer 170 may store the pixel values of a plurality of pixels PX coupled to a selected column line CL, received from the readout circuit 150, and may output the stored pixel values in response to an enable signal from the controller 110.

The image signal processor 180 may perform image signal processing on image signals received from the data buffer 170. For example, the image signal processor 180 may receive a plurality of image signals from the data buffer 170, and synthesize the received image signals to generate one image.

Hereinafter, various components which constitute pixels PX will be described in detail with reference to FIG. 2 and FIG. 3.

FIG. 2 is a circuit diagram for explaining the structure of a pixel PX included in the pixel array of FIG. 1, and FIG. 3 is a plan view for explaining the structure of a pixel PX included in the pixel array of FIG. 1.

Referring to FIG. 2 and FIG. 3, a pixel PX may output an electrical signal (charge) corresponding to the amount of incident light. In some embodiments, a pixel PX may include a photovoltaic device PD, a transfer transistor TX, a dual conversion gain transistor DCX, a first floating diffusion zone FD1, a second floating diffusion zone FD2, a reset transistor RX, a source follower transistor SX, and a selection transistor AX.

Hereinafter, the reference symbol “PXj” is used to indicate a specific pixel among the plurality of pixels PX1 to PXn, and a capacitor, a first electrode of the capacitor, a second electrode of the capacitor, a wiring line, and a via which are included in the corresponding pixel PXj are denoted by the reference symbols “PXj_MIM”, “PXj_MIM_1”, “PXj_MIM_2”, “PXj_Met”, and “VIAj”, respectively. However, in order to facilitate explanation and simplify the drawings, the photovoltaic device, the first and second floating diffusion zones, and the plurality of transistors which are included in a pixel PXj are denoted by reference symbols with no “j”.

The photovoltaic device PD may sense external images (or light) and generate charge. For example, the photovoltaic device PD may include an organic photodiode.

When the photovoltaic device PD is configured with an organic photodiode, the photovoltaic device PD may include a first electrode and a second electrode arranged in parallel with each other, and an organic photoconversion layer provided therebetween. In this case, the organic photoconversion layer may receive light in a predetermined wavelength band, and generate charge. The photovoltaic device PD may be a photodiode, a phototransistor, a photogate, a pinned photodiode, or a combination thereof, but the present disclosure is not limited thereto.

The transfer transistor TX may transfer charge generated by the photovoltaic device PD to the first floating diffusion zone FD1. The gate of the transfer transistor TX is also referred to as the transfer gate TG, and one of the ends of the transfer gate (i.e., one of the ends of the transfer transistor TX) may be coupled to the photovoltaic device PD, and the other end may be coupled to the first floating diffusion zone FD1. For example, the transfer transistor TX may be controlled by a transfer signal S_TG provided from the row driver 130. The transfer transistor TX may be electrically coupled to the photovoltaic device PD and the first floating diffusion zone FD1 on the basis of the transfer signal S_TG.

The dual conversion gain transistor DCX may couple the first floating diffusion zone FD1 and the second floating diffusion zone FD2 together. The gate of the dual conversion gain transistor DCX is also referred to as the dual conversion gain gate DCG, and one of the ends of the dual conversion gain gate (i.e., one of the ends of the dual conversion gain transistor DCX) may be coupled to the transfer transistor TX and the first floating diffusion zone FD1, and the other end may be coupled to the second floating diffusion zone FD2. For example, the dual conversion gain transistor DCX may adjust the amount of charge to be provided from the photovoltaic device PD and/or the first floating diffusion zone FD1 to the second floating diffusion zone FD2, on the basis of a dual conversion control signal S_DCG.

The first floating diffusion zone FD1 may store charge generated by the photovoltaic device PD. For example, the first floating diffusion zone FD1 may function as the drain of the transfer transistor TX. Also, the first floating diffusion zone FD1 may function as the source of the dual conversion gain transistor DCX. Further, the first floating diffusion zone FD1 may be electrically coupled to the gate of the source follower transistor SX which is also referred to as the source gate SF.

The second floating diffusion zone FD2 may store charge generated by the photovoltaic device PD, through the dual conversion gain transistor DCX. For example, the second floating diffusion zone FD2 may function as the drain of the dual conversion gain transistor DCX.

According to some embodiments, in order to implement an image sensor capable of efficiently operating in low-light environments and high-light environments, the capacitance of the second floating diffusion zone FD2 may be configured to be higher than the capacitance of the first floating diffusion zone FD1. For example, the second floating diffusion zone FD2 may include a metal-insulator-metal (MIM) capacitor PXj_MIM, but is not limited thereto, and may include various types of capacitors. Also, the area of the MIM capacitor PXj_MIM may be set as large as possible, to improve the capacitance of the second floating diffusion zone FD2.

The reset transistor RX may reset the voltage levels of the first and second floating diffusion zones FD1 and FD2 to a reset level V_RST. The gate of the reset transistor RX is also referred to as the reset gate RG, and one of the ends of the reset gate (i.e., one of the ends of the reset transistor RX) may be coupled to a power supply for supplying a pixel voltage V_PIX, and the other end may be coupled to the first and second floating diffusion zones FD1 and FD2. For example, the reset transistor RX may be controlled by a reset control signal S_RG provided from the row driver 130. The reset transistor RX may reset the voltage levels of the first and second floating diffusion zones FD1 and FD2 to a reset level V_RST, on the basis of a reset control signal S_RG.

The source follower transistor SX may output the levels of charge of the first and second floating diffusion zones FD1 and FD2 as output voltage V_OUT, using the pixel voltage V_PIX. One of the ends of the source gate SF (i.e., one of the ends of the source follower transistor SX) which is the gate of the source follower transistor SX may be coupled to the power supply for supplying the pixel voltage V_PIX, and the other end may be coupled to the selection transistor AX.

The selection transistor AX may output the output voltage V_OUT received from the source follower transistor SX to a column line CL coupled to the selection transistor AX. In this case, the output voltage V_OUT may be supplied to the readout circuit 150. For example, the selection transistor AX may be controlled by a selection signal S_SEL provided from the row driver 130. The gate of the selection transistor AX is also referred to as the selection gate SEL. The source terminal of the selection transistor AX may be coupled to the drain terminal of the source follower transistor SX, and the drain terminal of the selection transistor AX may be coupled to the column line CL.

The operation of the image sensor 100 according to some embodiments will be described with reference to FIG. 2 and FIG. 3 as follows. First, in a state where light is blocked out, the pixel voltage V_PIX is applied to the drain of the reset transistor RX and the drain of the source follower transistor SX, and the reset transistor RX and the dual conversion gain transistor DCX are turned on, such that the residual charge in the first and second floating diffusion zones FD1 and FD2 is discharged.

Then, the reset transistor RX is turned off, and external light is made to enter the photovoltaic device PD. As a result, in the photovoltaic device PD, electron-hole pairs are generated. The holes and the electrons move into the p-type impurity region and n-type impurity region of the photovoltaic device PD, and are accumulated in those regions, respectively.

Then, when the transfer transistor TX is turned on, charge such as electrons and holes is transferred to the first floating diffusion zone FD1 and is accumulated therein. When the amount of generated charge is large, the dual conversion gain transistor DCX is turned on. Then, the charge is transferred even to the second floating diffusion zone FD2 and is accumulated therein.

Thereafter, in proportion to the amounts of charge accumulated in the first floating diffusion zone FD1 and the second floating diffusion zone FD2, the gate bias for the source follower transistor SX changes, thereby changing the source potential of the source follower transistor SX. In this case, when the selection transistor AX is turned on, a signal based on the charge can be read into the column line CL.

FIG. 4 is a cross-sectional view taken along line A-A′ of FIG. 3.

Referring to FIG. 1 and FIG. 4, the image sensor 100 may include a light transmission layer 10, a photoelectric conversion layer 20, a plurality of transistors TX, RX, DCX, AX, and SX (see FIG. 3 for RX, AX, and SX), a first wiring layer 30, a second wiring layer 40, and a second substrate 50. For example, each of the plurality of pixels PX1 to PXn may include the light transmission layer 10, the photoelectric conversion layer 20, the first wiring layer 30, the second wiring layer 40, and the second substrate 50.

The light transmission layer 10 may concentrate and filter light entering from the outside. Referring to FIG. 4, the light transmission layer 10 may include a plurality of color filters (not shown in the drawing) and micro lenses ML.

The color filters may include primary color filters. The color filters may include first to third color filters having colors different from one another. As an example, the first to third color filters may include green, red, and blue color filters, respectively.

The micro lenses ML may have a convex shape such that the micro lenses ML can concentrate incident light on unit pixels PX. For example, the micro lenses ML may overlap the photovoltaic devices PD in a plan view (e.g., in a vertical direction). As used herein, “an element A overlaps an element B in a direction X” (or similar language) means that there is at least one line that extends in the direction X and intersects both the elements A and B.

The photoelectric conversion layer 20 may convert light passing through the light transmission layer 10 into an electrical signal (charge). Referring to FIG. 4, the photoelectric conversion layer 20 may include a first substrate 21 and a pixel separation pattern 22.

The first substrate 21 may have a first surface 21a and a second surface 21b facing each other. Light may enter from the first surface 21a. The light transmission layer 10 may be disposed on the first surface 21a, and the first wiring layer 30 may be disposed on the second surface 21b. As used herein, “a vertical direction” may refer to a direction perpendicular to the second surface 21b of the first substrate 21.

The first substrate 21 may be a semiconductor substrate or an SOI (silicon on insulator) substrate. Examples of the semiconductor substrate may include a silicon substrate, a germanium substrate, or a silicon-germanium substrate. The first substrate 21 may contain impurities of a first conductivity type. For example, the impurities of the first conductivity type may include p-type impurities such as aluminum (Al), boron (B), indium (In), and/or gallium (Ga).

Referring to FIG. 1 and FIG. 4, the first substrate 21 may include the plurality of pixels PX1 to PXn defined by the pixel separation pattern 22. Each of the plurality of pixels PX1 to PXn may include at least one photovoltaic device PD. The photovoltaic devices PD shown in FIG. 4 may correspond to the photovoltaic device PD shown in FIG. 2 and FIG. 3. The photovoltaic devices PD may be regions doped with impurities of a second conductivity type. The impurities of the second conductivity type may have the opposite conductivity to that of the impurities of the first conductivity type. The impurities of the second conductivity type may include n-type impurities such as phosphorus (P), arsenic (As), bismuth (Bi), and/or antimony (Sb).

The first substrate 21 and the photovoltaic devices PD may constitute photodiodes. When the first substrate 21 is of the first conductivity type and the photovoltaic devices PD are of the second conductivity type, by the p-n junctions between them, photodiodes may be configured. The photovoltaic devices PD which constitute the photodiodes may generate and accumulate charge in proportion to the intensity of incident light.

The pixel separation pattern 22 may be provided in the first substrate 21 so as to define the unit pixels PXj. The pixel separation pattern 22 may be provided between the plurality of pixels PX1 to PXn of the first substrate 21. The pixel separation pattern 22 may have a lattice structure as seen in a plan view. The pixel separation pattern 22 may completely surround each unit pixel PXj as seen in a plan view.

The plurality of transistors, i.e., the transfer transistors TX, the source follower transistors SX, the reset transistors RX, the dual conversion gain transistors DCX, and the selection transistors AX may be provided on the second surface 21b of the first substrate 21.

A gate dielectric layer GI may be interposed between the first substrate 21 and each of the gates of the plurality of transistors, i.e., the transfer gates TG, the source follower gates SF, the reset gates RG, the dual conversion gain gates DCG, and the selection gates SEL. On the upper surface and side surfaces of each of the gate electrodes TG, SF, RG, DCG, and SEL, gate spacers may be provided. The gate spacers may contain, for example, silicon nitride, silicon carbonitride, or silicon oxynitride.

Referring to FIG. 4, the transfer transistors TX may be electrically coupled to the photovoltaic devices PD. One side of each transfer gate TG which is the gate of a transfer transistor TX may be adjacent to a first floating diffusion zone FD1, and the other side thereof may be adjacent to a first impurity region (not shown in the drawing). While the first substrate 21 may contain impurities of the first conductivity type, the first floating diffusion zones FD1 may contain impurities of the second conductivity type. The bottom surface of the first impurity region may be spaced apart from the first floating diffusion zone FD1. The first impurity region is a doped region, and may contain impurities of the first conductivity type, similar to the first substrate 21.

Referring to FIG. 4, each dual conversion gain transistor DCX may electrically couple a first floating diffusion zone FD1 and a second floating diffusion zone FD2 together. One side of each dual conversion gain gate DCG which is the gate of a dual conversion gain transistor DCX may be adjacent to a first floating diffusion zone FD1, and the other side of the dual conversion gain gate DCG may be adjacent to a second floating diffusion zone FD2. For example, the second floating diffusion zones FD2 may contain impurities of the second conductivity type.

The first wiring layer 30 may include a plurality of insulating layers 31, 32, 33, and 34, a plurality of wiring lines PXj_Met_1, PXj_Met_2, and PXM_Met_TA, a plurality of vias VIAj_1, VIAj_2, and VIA_TA, and contacts CT to electrically couple a plurality of elements. The plurality of wiring lines PXj_Met_1, PXj_Met_2, and PXM_Met_TA, the plurality of vias VIAj_1, VIAj_2, and VIA_TA, and the contacts CT may contain a metal material. For example, the plurality of wiring lines PXj_Met_1, PXj_Met_2, and PXM_Met_TA, the plurality of vias VIAj_1, VIAj_2, and VIA_TA, and the contacts CT may contain copper (Cu).

According to some embodiments, the first wiring layer 30 may include the MIM capacitors PXj_MIM which constitute the second floating diffusion zones FD2. The MIM capacitors PXj_MIM may include first electrodes PXj_MIM_1 and second electrodes PXj_MIM_2 overlapping each other. Moreover, the MIM capacitors PXj_MIM may further include the dielectric layer GI located between the first electrodes PXj_MIM_1 and the second electrodes PXj_MIM_2. The first electrodes PXj_MIM_1 are electrically coupled to the photovoltaic devices PD through the first wiring lines PXj_Met_1, the second wiring lines PXj_Met_2, the first vias VIAj_1, the second vias VIAj_2, and the contacts CT. The second electrodes PXj_MIM_2 are electrically coupled to a ground GND through the third wiring lines PXM_Met_TA and the third vias VIA_TA.

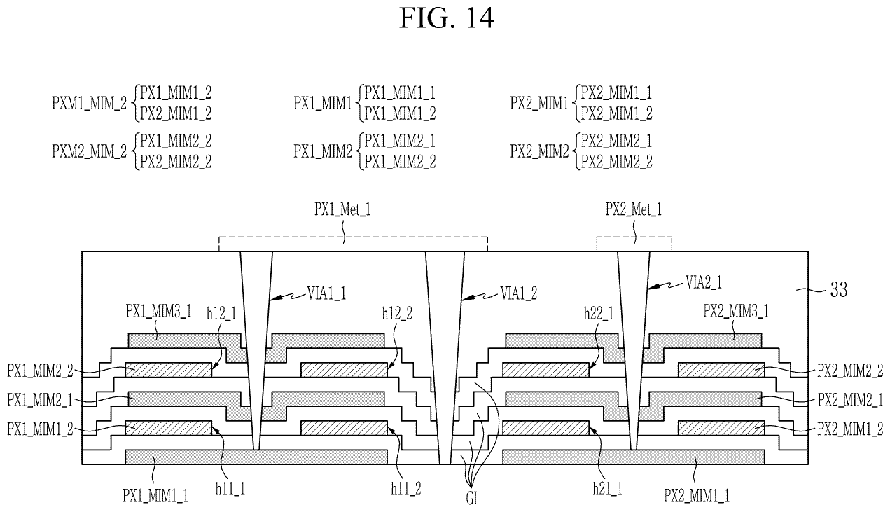

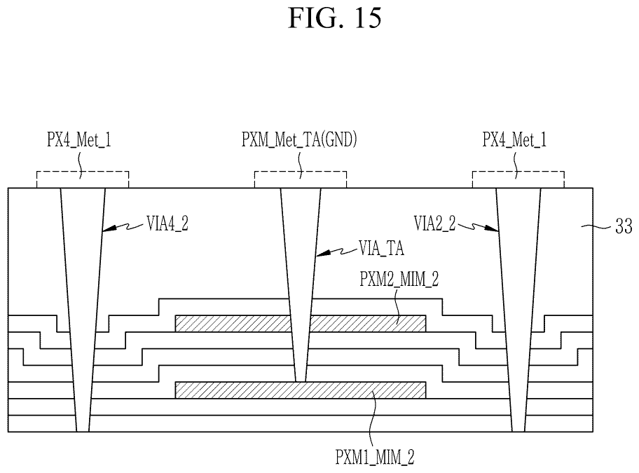

According to some embodiments, the first wiring layer 30 may include a plurality of MIM capacitors. For example, the plurality of MIM capacitors may form laminate structures in the first wiring layer 30. This will be described below in detail with reference to FIG. 14 and FIG. 15.

The plurality of insulating layers 31, 32, 33, and 34 may include a first insulating layer 31, a second insulating layer 32, a third insulating layer 33, and a fourth insulating layer 34. The plurality of insulating layers 31, 32, 33, and 34 may contain a non-conductive material. For example, the plurality of insulating layers 31, 32, 33, and 34 may contain silicon-based insulating materials such as silicon oxide, silicon nitride, and/or silicon oxynitride.

The first insulating layer 31 may cover the second surface 21b of the first substrate 21. The second insulating layer 32 may be located on the first insulating layer 31. The first insulating layer 31 and the second insulating layer 32 may cover the gate electrodes TG, SEL, SF, RG, and DCG. The third insulating layer 33 may be located on the second insulating layer 32, and the fourth insulating layer 34 may be located on the third insulating layer 33.

In some embodiments, the MIM capacitors PXj_MIM which constitute the second floating diffusion zones FD2 may be located in the third insulating layer 33, but are not limited thereto, and may be located in any one of the plurality of insulating layers 31, 32, 33, and 34.

The plurality of wiring lines PXj_Met_1, PXj_Met_2, and PXM_Met_TA may include first wiring lines PXj_Met_1, second wiring lines PXj_Met_2, and third wiring lines PXM_Met_TA. For example, the second wiring lines PXj_Met_2 may be located in the third insulating layer 33, and the first wiring lines PXj_Met_1 and the third wiring lines PXM_Met_TA may be located in the fourth insulating layer 34.

The first wiring lines PXj_Met_1 may be electrically coupled to the first electrodes PXj_MIM_1 of the MIM capacitors PXj_MIM through the first vias VIAj_1. The first wiring lines PXj_Met_1 may be electrically coupled to the first electrodes PXj_MIM_1 and the photovoltaic devices PD.

The second wiring lines PXj_Met_2 may be electrically coupled to the first wiring lines PXj_Met_1 through the second vias VIAj_2. The second wiring lines PXj_Met_2 may be vertically coupled to the second floating diffusion zones FD2 through the contacts CT. In this case, the contacts CT may pass (i.e., extend) through the first insulating layer 31 and the second insulating layer 32. However, the coupling of the second wiring lines PXj_Met_2 is not limited to that shown in FIG. 4, and the second wiring lines PXj_Met_2 may be vertically coupled to the transfer transistors TX, the source follower transistors SX, the reset transistors RX, the dual conversion gain transistors DCX, and the selection transistors AX through the contacts CT. Further, the contacts CT corresponding to the gate electrodes TG, SEL, SF, RG, and DCG may pass through gate spacers GS.

According to some embodiments, charge generated by the photovoltaic devices PD may be transferred to the first floating diffusion zones FD1 through the transfer transistors TX, and some of the charge stored in the first floating diffusion zones FD1 may be transferred to the second floating diffusion zones FD2 through the dual conversion gain transistors DCX. The charge transferred to the second floating diffusion zones FD2 may be transferred to the first electrodes PXj_MIM_1 of the MIM capacitors PXj_MIM through the contacts CT, the second wiring lines PXj_Met_2, the second vias VIAj_2, the first wiring lines PXj_Met_1, and the first vias VIAj_1.

The third wiring lines PXM_Met_TA may be electrically coupled to the second electrodes PXj_MIM_2 of the MIM capacitors PXj_MIM through the third vias VIA_TA. The third wiring lines PXM_Met_TA may electrically couple the ground GND to the second electrodes PXj_MIM_2 of the MIM capacitors PXj_MIM.

The second wiring layer 40 may be located on the first wiring layer 30. The second substrate 50 may be located on the second wiring layer 40.

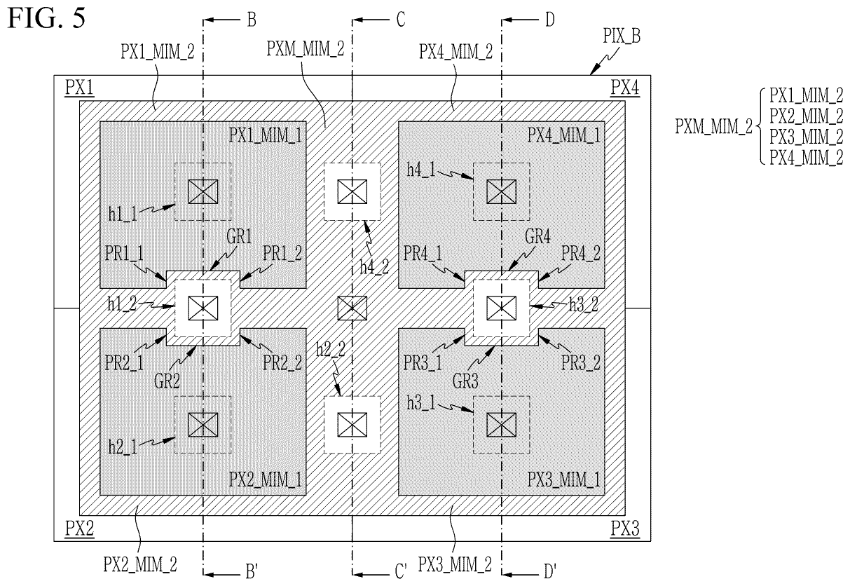

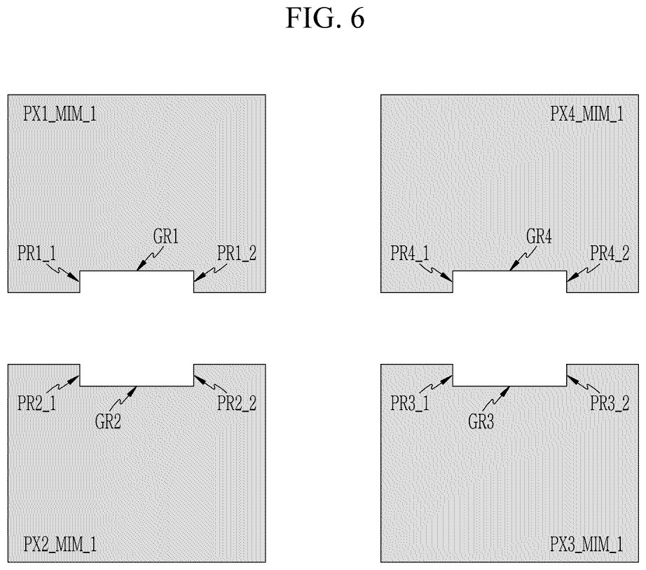

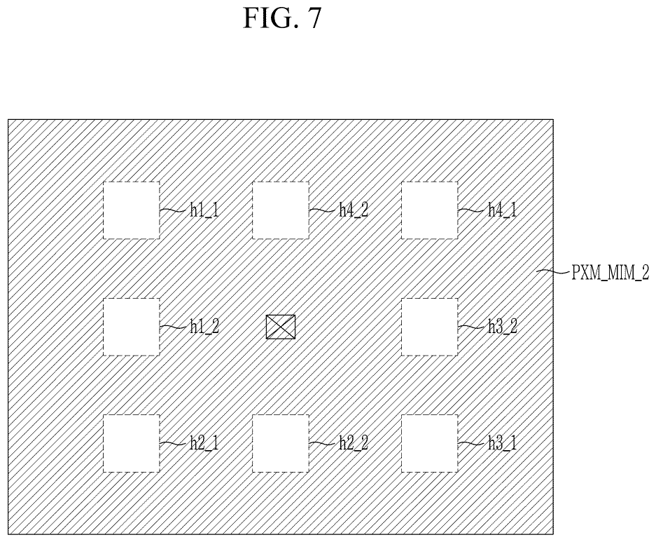

FIG. 5 is an enlarged plan view illustrating MIM capacitors which constitute second floating diffusion zones in region M of FIG. 1, FIG. 6 is a plan view illustrating first electrodes of the MIM capacitors shown in FIG. 5, and FIG. 7 is a plan view illustrating a common electrode corresponding to the second electrodes of the MIM capacitors shown in FIG. 5.

Referring to FIG. 1, FIG. 4, and FIG. 5, region M is a pixel group including a plurality of pixels PX1 to PXn adjacent to one another. For example, region M may include first to fourth pixels PX1, PX2, PX3, and PX4.

Referring to FIG. 5, according to some embodiments, the second floating diffusion zone FD2 of each of the first to fourth pixels PX1, PX2, PX3, and PX4 may include a MIM capacitor PXj_MIM. However, the second floating diffusion zones FD2 are not limited thereto, and may include various types of capacitors having high capacitance.

The second floating diffusion zone FD2 of the first pixel PX1 may include a first MIM capacitor PX1_MIM. The first MIM capacitor PX1_MIM may include a first electrode PX1_MIM_1 and a second electrode PX1_MIM_2.

The second floating diffusion zone FD2 of the second pixel PX2 may include a second MIM capacitor PX2_MIM. The second MIM capacitor PX2_MIM may include a first electrode PX2_MIM_1 and a second electrode PX2_MIM_2.

The second floating diffusion zone FD2 of the third pixel PX3 may include a third MIM capacitor PX3_MIM. The third MIM capacitor PX3_MIM may include a first electrode PX3_MIM_1 and a second electrode PX3_MIM_2.

The second floating diffusion zone FD2 of the fourth pixel PX4 may include a fourth MIM capacitor PX4_MIM. The fourth MIM capacitor PX4_MIM may include a first electrode PX4_MIM_1 and a second electrode PX4_MIM_2.

Referring to FIG. 5 and FIG. 6, the plurality of second electrodes PX1_MIM_2, PX2_MIM_2, PX3_MIM_2, and PX4_MIM_2 of the first to fourth MIM capacitors PX1_MIM, PX2_MIM, PX3_MIM, and PX4_MIM may be integrally formed (i.e., may be integral with each other). According to some embodiments, when a plurality of pixels PX1 to PXn is included in region M, a plurality of second electrodes PX1_MIM_2 to PXn_MIM_2 of a plurality of MIM capacitors PX1_MIM to PXn_MIM may be integrally formed (i.e., may be integral with each other).

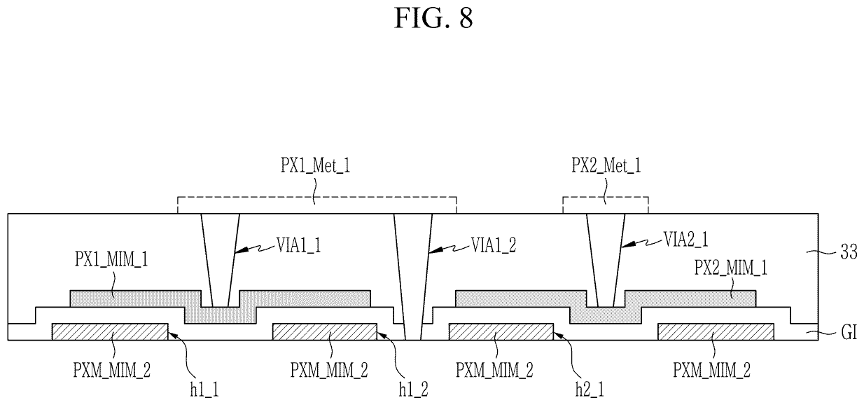

Referring to FIG. 7, a second electrode PXM_MIM_2 integrally formed may include a plurality of holes h1_1, h1_2, h2_1, h2_2, h3_1, h3_2, h4_1, and h4_2. As an example, the plurality of holes denoted by the reference symbols h1_1, h2_1, h3_1, and h4_1 with a suffix number “1” may overlap the first electrodes PXj_MIM_1 of the MIM capacitors PXj_MIM, respectively. As another example, the plurality of holes denoted by the reference symbols h1_2, h2_2, h3_2, and h4_2 with a suffix number “2” may not overlap the first electrodes PXj_MIM_1 of the MIM capacitors PXj_MIM, respectively. This will be described below in detail with reference to FIGS. 8 to 10.

Referring to FIG. 5 and FIG. 6, the plurality of first electrodes PX1_MIM_1, PX2_MIM_1, PX3_MIM_1, and PX4_MIM_1 of the first to fourth MIM capacitors PX1_MIM, PX2_MIM, PX3_MIM, and PX4_MIM may be located so as to be apart from one another (i.e., spaced apart from one another) by predetermined distances. According to some embodiments, the plurality of first electrodes PX1_MIM_1, PX2_MIM_1, PX3_MIM_1, and PX4_MIM_1 of the first to fourth MIM capacitors PX1_MIM, PX2_MIM, PX3_MIM, and PX4_MIM may be arranged along a row direction and a column direction.

One edge of the first electrode PX1_MIM_1 of the first pixel PX1 may include a first groove GR1 of the first pixel PX1 adjacent to the second hole h1_2 of the first pixel PX1, and two first protrusions PR1_1 and PR1_2 of the first pixel PX1 that are located on both sides of the first groove GR1, respectively. Further, one edge of the first electrode PX2_MIM_1 of the second pixel PX2 may include a first groove GR2 of the second pixel PX2 adjacent to the second hole h1_2 of the first pixel PX1, and two first protrusions PR2_1 and PR2_2 of the second pixel PX2 that are located on both sides of the first groove GR2, respectively. Furthermore, one edge of the first electrode PX3_MIM_1 of the third pixel PX3 may include a first groove GR3 of the third pixel PX3 adjacent to the second hole h3_2 of the third pixel PX3, and two first protrusions PR3_1 and PR3_2 of the third pixel PX3 that are located on both sides of the first groove GR3, respectively. Moreover, one edge of the first electrode PX4_MIM_1 of the fourth pixel PX4 may include a first groove GR4 of the fourth pixel PX4 adjacent to the second hole h3_2 of the third pixel PX3, and two first protrusions PR4_1 and PR4_2 of the fourth pixel PX4 that are located on both sides of the first groove GR4, respectively.

In FIG. 5 and FIG. 6, the plurality of grooves GR1, GR2, GR3, and GR4 and the plurality of protrusions PR1_1, PR1_2, PR2_1, PR2_2, PR3_1, PR3_2, PR4_1, and PR4_2 are shown around the second hole h1_2 of the first pixel PX1 and the second hole h3_2 of the third pixel PX3; however, the present disclosure is not limited thereto. The plurality of grooves GR1, GR2, GR3, and GR4 and the plurality of protrusions PR1_1, PR1_2, PR2_1, PR2_2, PR3_1, PR3_2, PR4_1, and PR4_2 may be formed around or adjacent to the second hole h2_2 of the second pixel PX2 and the second hole h4_2 of the fourth pixel PX4.

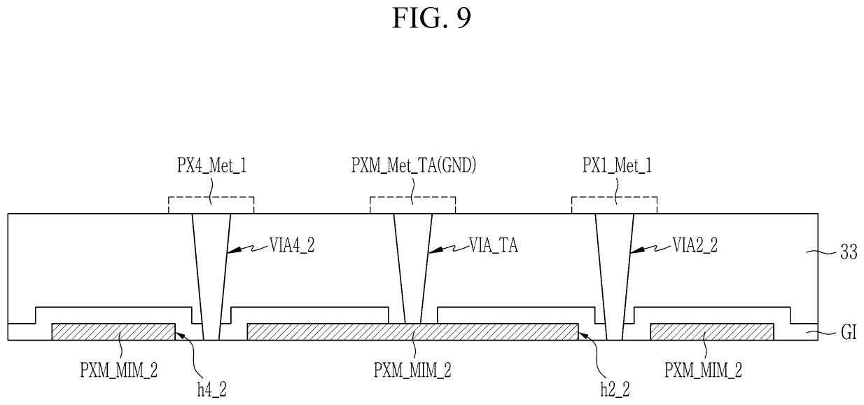

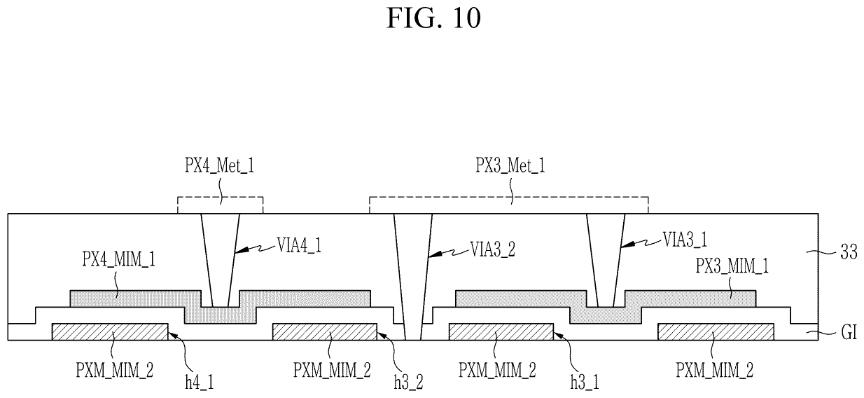

FIG. 8 is a cross-sectional view taken along line B-B′ of FIG. 5, FIG. 9 is a cross-sectional view taken along line C-C′ of FIG. 5, and FIG. 10 is a cross-sectional view taken along line D-D′ of FIG. 5. For convenience, the second wiring line PXj_Met_2 is omitted in FIGS. 8-9.

Referring to FIG. 4, FIG. 5, and FIG. 8, the first electrode PX1_MIM_1 of the first pixel PX1 may be electrically coupled to a photovoltaic device PD through the first wiring line PX1_Met_1. Between the first electrode PX1_MIM_1 and the first wiring line PX1_Met_1, the third insulating layer 33 may be located. Further, the first via VIA1_1 may pass (i.e., extend) through the third insulating layer 33 so as to electrically couple the first electrode PX1_MIM_1 and the first wiring line PX1_Met_1 together. Furthermore, the first pixel PX1 may further include the second via VIA1_2 that passes (i.e., extends) through the third insulating layer 33 and the dielectric layer GI located between the first electrode PX1_MIM_1 and the second electrode PXM_MIM_2 so as to be coupled to the first wiring line PX1_Met_1.

The second electrode PXM_MIM_2 of the first pixel PX1 may include the first hole h1_1 overlapping the first via VIA1_1. The first hole h1_1 may overlap the first electrode PX1_MIM_1. Further, the second electrode PXM_MIM_2 may include the second hole h1_2 overlapping the second via VIA1_2. The second hole h1_2 may be located between the first electrode PX1_MIM_1 of the first pixel PX1 and the first electrode PX2_MIM_1 of the second pixel PX2, so as not to overlap the first electrode PX1_MIM_1 of the first pixel PX1. That is, the second hole h1_2 may be free of overlap (e.g., in a vertical direction) with the first electrode PX1_MIM_1 of the first pixel PX1 and the first electrode PX2_MIM_1 of the second pixel PX2.

Referring to FIG. 4, FIG. 5, and FIG. 9, a common electrode PXM_MIM_2 for the first to fourth MIM capacitors may be coupled to the ground through a third wiring line PXM_Met_TA. Between the common electrode PXM_MIM_2 and the third wiring line PXM_Met_TA, the third insulating layer 33 may be located. Further, a third via VIA_TA may pass (i.e., extend) through the third insulating layer 33 so as to electrically couple the second electrode PX2_MIM_2 (i.e., the common electrode PXM_MIM_2) and the third wiring line PXM_Met_TA together.

Referring to FIG. 4, FIG. 5, and FIG. 10, the first electrode PX3_MIM_1 of the third pixel PX3 may be electrically coupled to the first wiring line PX3_Met_1 of the third pixel PX3 through the first via VIA3_1. In other words, the first electrode PX3_MIM_1 of the third pixel PX3 may be electrically coupled to the second floating diffusion zone FD2 of the third pixel PX3.

The first electrode PX3_MIM_1 may be electrically coupled to a photovoltaic device PD through the first wiring line PX3_Met_1. Between the first electrode PX3_MIM_1 and the first wiring line PX3_Met_1, the third insulating layer 33 may be located. Further, the second via VIA3_2 may pass (i.e., extend) through the third insulating layer 33 so as to electrically couple the first electrode PX3_MIM_1 and the second wiring line PX3_Met_2 together (see FIG. 4). Furthermore, the third pixel PX3 may further include the second via VIA3_2 which passes (i.e., extends) through the third insulating layer 33 and the dielectric layer GI located between the first electrode PX3_MIM_1 and the second electrode PXM_MIM_2 so as to be coupled to the first wiring line PX3_Met_1.

The second electrode PXM_MIM_2 may include the first hole h3_1 overlapping the first via VIA3_1. The first hole h3_1 may overlap the first electrode PX3_MIM_1. Further, the second electrode PXM_MIM_2 may include the second hole h3_2 overlapping the second via VIA3_2. The second hole h3_2 may be located between the first electrode PX3_MIM_1 of the third pixel PX3 and the first electrode PX4_MIM_1 of the fourth pixel PX4, so as not to overlap the first electrode PX3_MIM_1 of the third pixel PX3 and the first electrode PX4_MIM_1 of the fourth pixel PX4. That is, the second hole h3_2 may be free of overlap (e.g., in a vertical direction) with the first electrode PX3_MIM_1 of the third pixel PX3 and the first electrode PX4_MIM_1 of the fourth pixel PX4.

The second electrode PXM_MIM_2 of the fourth pixel PX4 may include the first hole h4_1 overlapping the first via VIA4_1. The first hole h4_1 may overlap the first electrode PX4_MIM_1 of the fourth pixel PX4. Referring to FIG. 9, the second electrode PXM_MIM_2 may include the second hole h4_2 overlapping the second via VIA4_2 of the fourth pixel PX4. Referring to FIG. 5, the second hole h4_2 may be located between the first electrode PX1_MIM_1 of the first pixel PX1 and the first electrode PX4_MIM_1 of the fourth pixel PX4 so as not to overlap the first electrode PX1_MIM_1 of the first pixel PX1 and the first electrode PX4_MIM_1 of the fourth pixel PX4. That is, the second hole h4_2 may be free of overlap (e.g., in a vertical direction) with the first electrode PX1_MIM_1 of the first pixel PX1 and the first electrode PX4_MIM_1 of the fourth pixel PX4.

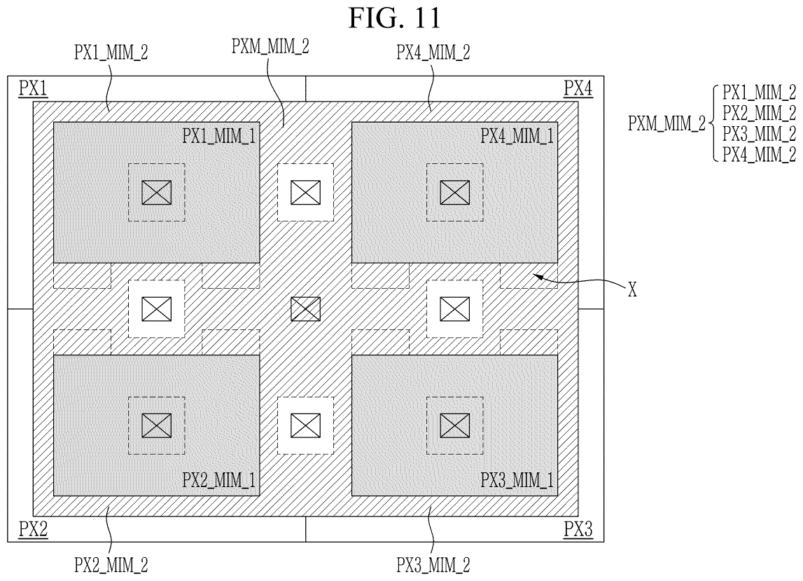

FIG. 11 is an enlarged plan view illustrating MIM capacitors which constitute second floating diffusion zones according to some embodiments.

Referring to FIG. 11, the first electrodes PXj_MIM_1 of a plurality of pixels PX1 to PX4 sharing a second electrode PXj_MIM_2 integrally formed may consist of a plurality of lines located so as to be apart from the plurality of holes h1_1, h1_2, h2_1, h2_2, h3_1, h3_2, h4_1, and h4_2 formed in the second electrode PXj_MIM_2 by a predetermined distance.

The first electrode PXj_MIM_1 of each of the plurality of pixels PX1 to PX4 shown in FIG. 5 may have an area larger than that of the first electrode PXj_MIM_1 of each of the plurality of pixels PX1 to PX4 shown in FIG. 11 by a predetermined area X.

According to some embodiments, in a pixel group in which a second electrode PXj_MIM_2 is shared, some pixels may include MIM capacitors having the form of a first electrode PXj_MIM_1 shown in FIG. 5, and some other pixels may include MIM capacitors having the form of a first electrode PXj_MIM_1 shown in FIG. 11. In other words, the forms (e.g., areas) of the plurality of first electrodes of a plurality of MIM capacitors included in a pixel group may be different from each other.

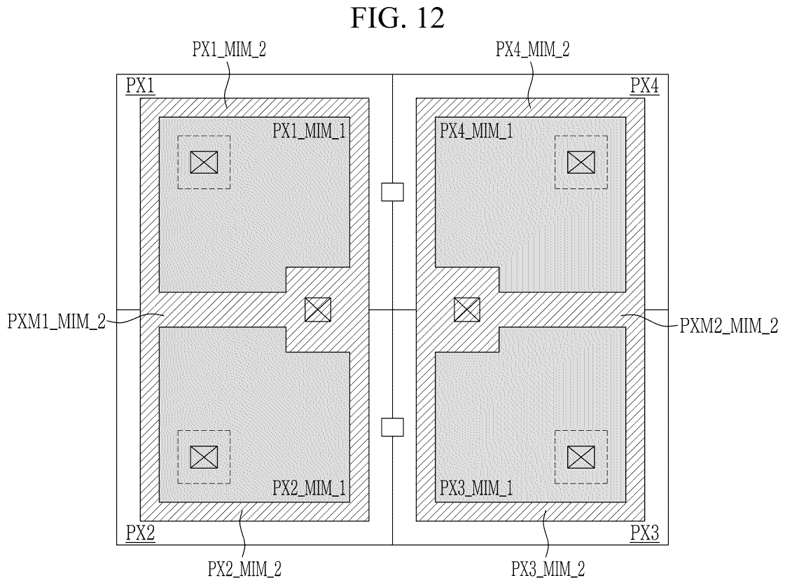

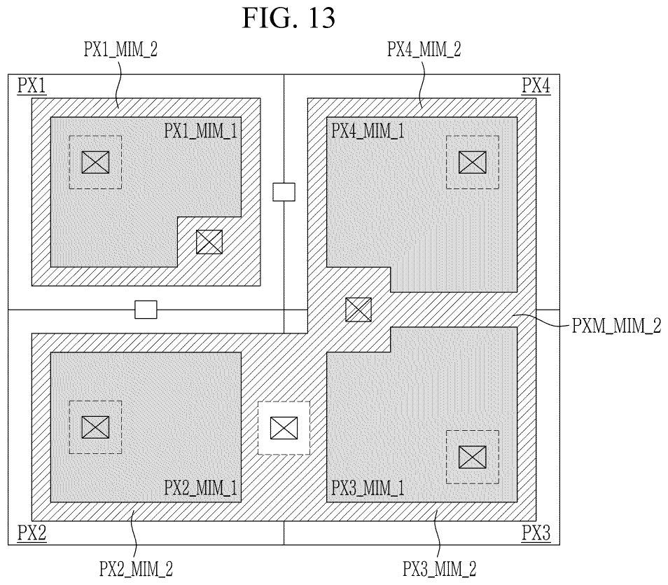

FIG. 12 and FIG. 13 are enlarged plan views illustrating MIM capacitors which constitute second floating diffusion zones according to some embodiments.

The pixel array 140 (see FIG. 1) may include a plurality of pixel groups, each of which may include at least two pixels. For example, the pixel array 140 may include a first pixel group including a first pixel PX1 and a second pixel PX2. As another example, the pixel array 140 may include a second pixel group including a third pixel PX3, a fourth pixel PX4, and a fifth pixel PX5.

Referring to FIG. 12, the pixel array 140 may include pixel groups, in each of which a first pixel PX1 and a second pixel PX2 share a second electrode PXj_MIM_2 integrally formed (e.g., a first common electrode PXM1_MIM_2). The pixel array 140 may include pixel groups, in each of which a third pixel PX3 and a fourth pixel PX4 share a second electrode PXj_MIM_2 integrally formed (e.g., a second common electrode PXM2_MIM_2).

Referring to FIG. 13, the pixel array 140 may include pixel groups, in each of which a second pixel PX2, a third pixel PX3, and a fourth pixel PX4 share a second electrode PXj_MIM_2 integrally formed (e.g., a common electrode PXM_MIM_2).

However, the present disclosure is not limited to the pixel groups shown in FIG. 12 and FIG. 13 and the forms of the plurality of first electrodes PXj_MIM_1 included in those pixel groups, and pixel groups including various numbers of pixels may be formed. Further, the form of the first electrodes of a plurality of MIM capacitors included in a pixel group is not limited to those shown in FIG. 12 and FIG. 13, and may be changed variously.

FIG. 14 is an enlarged first cross-sectional view illustrating a plurality of MIM capacitors which constitute second floating diffusion zones according to some embodiments, and FIG. 15 is an enlarged second cross-sectional view illustrating a plurality of MIM capacitors which constitute second floating diffusion zones according to some embodiments. For convenience, the second wiring line PXj_Met_2 is omitted in FIGS. 14-15.

According to some embodiments, plan views corresponding to FIG. 14 and FIG. 15 may be equal to FIG. 5. Specifically, it is assumed that each of the first pixel PX1 to the fourth pixel PX4 shown in FIG. 5 includes a plurality of MIM capacitors PXj_MIM1 to PXj_MIMn stacked. FIG. 14 may correspond to a cross-sectional view taken along line B-B′ of FIG. 5. FIG. 15 may correspond to a cross-sectional view taken along line C-C′ of FIG. 5.

For example, the first pixel PX1 may include first to third MIM capacitors PX1_MIM1, PX1_MIM2, and PX1_MIM3. The second pixel PX2 may include first to third MIM capacitors PX2_MIM1, PX2_MIM2, and PX2_MIM3. The third pixel PX3 may include first to third MIM capacitors PX3_MIM1, PX3_MIM2, and PX3_MIM3. The fourth pixel PX4 may include first to third MIM capacitors PX4_MIM1, PX4_MIM2, and PX4_MIM3. In FIG. 14 and FIG. 15, it is shown that in one pixel PXj, three MIM capacitors are stacked; however, the present disclosure is not limited thereto, and in one pixel PXj, various numbers of MIM capacitors may be stacked.

Referring to FIG. 14, in the first pixel PX1, the first MIM capacitor PX1_MIM1 may include a first electrode PX1_MIM1_1 and a second electrode PX1_MIM1_2. The second MIM capacitor PX1_MIM2 may include a first electrode PX1_MIM2_1 and a second electrode PX1_MIM2_2. The third MIM capacitor PX1_MIM3 may include a first electrode PX1_MIM3_1.

In some embodiments, the first pixel PX1 may not include a second electrode for the third MIM capacitor PX1_MIM3. In the case where it is not required to form a second electrode for the third MIM capacitor PX1_MIM3, it is possible to simplify the process, and a dedicated space for the second electrode may not be required. However, the present disclosure is not limited thereto, and according to some embodiments, the third MIM capacitor PX1_MIM3 may include a second electrode.

Specifically, between the first electrode PX1_MIM1_1 and the second electrode PX1_MIM1_2, charge may be stored. Between the second electrode PX1_MIM1_2 and the first electrode PX1_MIM2_1, charge may be stored. Between the first electrode PX1_MIM2_1 and the second electrode PX1_MIM2_2, charge may be stored. Between the second electrode PX1_MIM2_2 and the first electrode PX1_MIM3_1, charge may be stored. In this case, the charge may be charge generated by a photovoltaic device PD.

According to some embodiments, the second electrode PX1_MIM1_2 may be stacked on the first electrode PX1_MIM1_1, the first electrode PX1_MIM2_1 may be stacked on the second electrode PX1_MIM1_2, the second electrode PX1_MIM2_2 may be stacked on the first electrode PX1_MIM2_1, and the first electrode PX1_MIM3_1 may be stacked on the second electrode PX1_MIM2_2. Between the plurality of electrodes, dielectric layers GI may be formed.

In the second pixel PX2, the first MIM capacitor PX2_MIM1 may include a first electrode PX2_MIM1_1 and a second electrode PX2_MIM1_2. The second MIM capacitor PX2_MIM2 may include a first electrode PX2_MIM2_1 and a second electrode PX2_MIM2_2. The third MIM capacitor PX2_MIM3 may include a first electrode PX2_MIM3_1. However, the third MIM capacitor PX2_MIM3 is not limited thereto, and may further include a second electrode.

Specifically, between the first electrode PX2_MIM1_1 and the second electrode PX2_MIM1_2, charge may be stored. Between the second electrode PX2_MIM1_2 and the first electrode PX2_MIM2_1, charge may be stored. Between the first electrode PX2_MIM2_1 and the second electrode PX2_MIM2_2, charge may be stored. Between the second electrode PX2_MIM2_2 and the first electrode PX2_MIM3_1, charge may be stored. In this case, the charge may be charge generated by a photovoltaic device PD.

According to some embodiments, in the second pixel PX2, the second electrode PX2_MIM1_2 may be stacked on the first electrode PX2_MIM1_1, the first electrode PX2_MIM2_1 may be stacked on the second electrode PX2_MIM1_2, the second electrode PX2_MIM2_2 may be stacked on the first electrode PX2_MIM2_1, and the first electrode PX2_MIM3_1 may be stacked on the second electrode PX2_MIM2_2. Between the plurality of electrodes, dielectric layers GI may be formed.

Referring to FIG. 14, the plurality of first electrodes PX1_MIM1_1, PX1_MIM2_1, and PX1_MIM3_1 of the first pixel PX1 may be electrically coupled to a photovoltaic device PD through a first wiring line PX1_Met_1. Further, the first via VIA1_1 may pass (i.e., extend) through the third insulating layer 33 so as to electrically couple the plurality of first electrodes PX1_MIM1_1, PX1_MIM2_1, and PX1_MIM3_1 to the first wiring line PX1_Met_1. Furthermore, the first pixel PX1 may further include a second via VIA1_2 which passes (i.e., extends) through the dielectric layers GI and the third insulating layer 33 so as to be coupled to the first wiring line PX1_Met_1.

Referring to FIG. 15, the second electrode PX1_MIM1_2 of the first pixel PX1 and the second electrode PX2_MIM1_2 of the second pixel PX2 may be integrally formed (i.e., may be integral with each other) so as to form a first common electrode PXM1_MIM_2. The second electrode PX1_MIM2_2 of the first pixel PX1 and the second electrode PX2_MIM2_2 of the second pixel PX2 may be integrally formed (i.e., may be integral with each other) so as to form a second common electrode PXM2_MIM_2. Further, the first common electrode PXM1_MIM_2 and the second common electrode PXM2_MIM_2 may be coupled to the ground through a third wiring line PXM_Met_TA. Furthermore, a third via VIA_TA may pass (i.e., extend) through the third insulating layer 33 so as to electrically couple the first common electrode PXM1_MIM_2, the second common electrode PXM2_MIM_2, and the third wiring line PXM_Met_TA together.

Referring to FIG. 14 and FIG. 15, the first common electrode PXM1_MIM_2 may include a first hole h11_1 overlapping the first via VIA1_1. The first hole h11_1 may overlap the first electrode PX1_MIM2_1. Further, the first common electrode PXM1_MIM_2 may include a second hole h11_2 overlapping the second via VIA1_2. The second hole h11_2 may be located between the first electrode PX1_MIM2_1 of the first pixel PX1 and the first electrode PX2_MIM2_1 of the second pixel PX2 so as not to overlap the first electrode PX1_MIM2_1 of the first pixel PX1 and the first electrode PX2_MIM2_1 of the second pixel PX2. That is, the second hole h11_2 may be free of overlap (e.g., in a vertical direction) with the first electrode PX1_MIM2_1 of the first pixel PX1 and the first electrode PX2_MIM2_1 of the second pixel PX2. Moreover, the first common electrode PXM1_MIM_2 may include a first hole h21_1 overlapping the first via VIA2_1.

The second common electrode PXM2_MIM_2 may include a first hole h12_1 overlapping a first via VIA1_1. The first hole h12_1 may overlap the first electrode PX1_MIM3_1. Further, the second common electrode PXM2_MIM_2 may include a second hole h12_2 overlapping a second via VIA1_2. The second hole h12_2 may be located between the first electrode PX1_MIM3_1 of the first pixel PX1 and the first electrode PX2_MIM3_1 of the second pixel PX2 so as not to overlap the first electrode PX1_MIM3_1 of the first pixel PX1 and the first electrode PX2_MIM3_1 of the second pixel PX2. That is, the second hole h12_2 may be free of overlap (e.g., in a vertical direction) with the first electrode PX1_MIM3_1 of the first pixel PX1 and the first electrode PX2_MIM3_1 of the second pixel PX2. Further, the second common electrode PXM2_MIM_2 may include a first hole h22_1 overlapping the first via VIA2_1

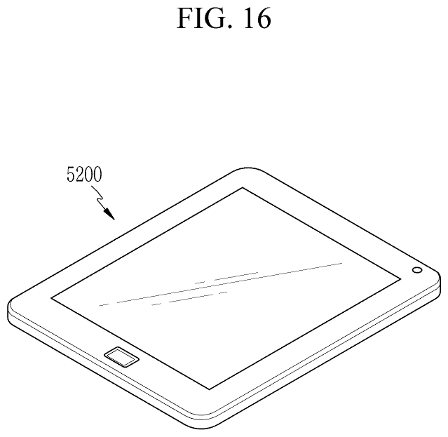

Hereinafter, examples of application of an image sensor according to some embodiments will be described with reference to FIGS. 16 to 18.

FIGS. 16 to 18 are views illustrating examples of electronic devices to which an image sensor according to some embodiments has been applied.

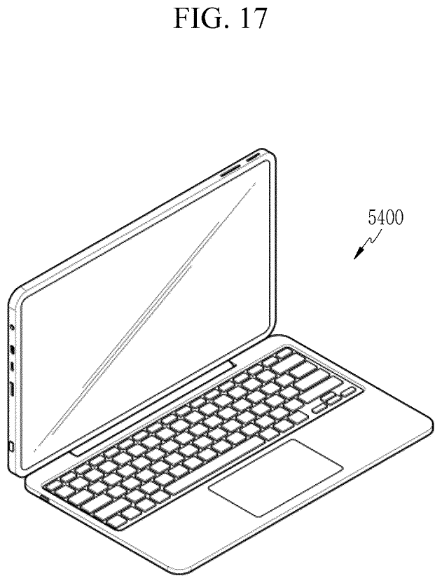

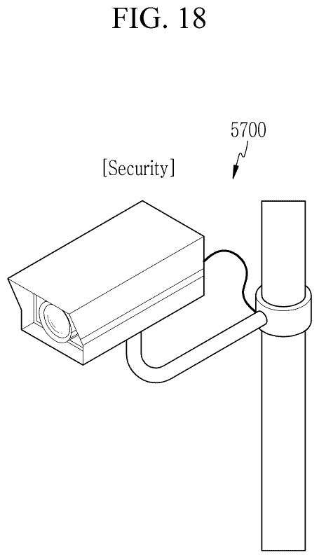

The image sensors 100 according to some embodiments may be applied to mobile phones or smart phones, a tablet or smart tablet 5200 shown in FIG. 16, a laptop 5400 shown in FIG. 17, a security camera 5700 shown in FIG. 18, etc. For example, a smart phone or the smart tablet 5200 may include a plurality of high-definition cameras equipped with high-definition image sensors. High-definition cameras may be used to extract depth information on objects in images, adjust the shallow depth of field in an image, and/or automatically identify objects in images. The security camera 5700 may provide ultra-high-definition images and may use high sensitivity to make it possible to recognize objects or people in images even in dark environments.

While this disclosure has been described in connection with example embodiments thereof, it is to be understood that the disclosure is not limited to the disclosed embodiments. On the contrary, it is intended to cover various modifications and equivalent arrangements included within the scope of the appended claims.

What is claimed is:

1. An image sensor comprising:
a plurality of pixels, each of which includes a photovoltaic device configured to convert incident light into charge, and a capacitor configured to store the charge,
wherein the capacitor of each of the plurality of pixels comprises:
a first electrode and a second electrode that overlap each other; and
a dielectric layer that is between the first electrode and the second electrode,
wherein the plurality of pixels include a first pixel and a second pixel adjacent to each other, and
wherein the second electrode of the first pixel and the second electrode of the second pixel are integral with each other.

2. The image sensor of claim 1, wherein the first electrode of the capacitor is coupled to the photovoltaic device, and
wherein the second electrode of the capacitor is coupled to a ground.

3. The image sensor of claim 1, further comprising:
a first wiring line that is coupled between the photovoltaic device and the first electrode of the capacitor;
a first insulating layer that is between the first electrode of the capacitor and the first wiring line; and
a first via that extends through the first insulating layer so as to couple the first electrode of the capacitor and the first wiring line together.

4. The image sensor of claim 3, wherein the second electrode includes a first hole that overlaps the first via, and
wherein the first hole overlaps the first electrode of the capacitor.

5. The image sensor of claim 3, wherein the first electrode of the first pixel and the first electrode of the second pixel are spaced apart from each other.

6. The image sensor of claim 5, further comprising a second via that extends through the first insulating layer and the dielectric layer so as to be coupled to the first wiring line.

7. The image sensor of claim 6, wherein the second electrode includes a second hole that overlaps the second via, and
wherein the second hole is free of overlap in a vertical direction with the first electrode of the capacitor.

8. The image sensor of claim 7, wherein the second hole is between the first electrode of the first pixel and the first electrode of the second pixel.

9. The image sensor of claim 8, wherein one edge of the first electrode of the first pixel comprises:
a first groove that is adjacent to the second hole; and
first protrusions that are on both sides of the first groove, respectively,
wherein one edge of the first electrode of the second pixel comprises:
a second groove that is adjacent to the second hole; and
second protrusions that are on both sides of the second groove, respectively, and
wherein the second hole is at least partially surrounded by the first groove, the first protrusions, the second groove, and the second protrusions.

10. The image sensor of claim 1, wherein the plurality of pixels further include a third pixel and a fourth pixel adjacent to the first pixel and the second pixel, and
wherein the second electrode of the first pixel, the second electrode of the second pixel, the second electrode of the third pixel, and the second electrode of the fourth pixel are integral with each other.

11. The image sensor of claim 10, wherein the first pixel, the second pixel, the third pixel, and the fourth pixel are arranged along a row direction and a column direction.

12. The image sensor of claim 1, wherein the second electrodes of the plurality of pixels are integral with each other.

13. An image sensor comprising:
a plurality of pixels, each of which comprises:
a photovoltaic device configured to convert incident light into charge;
a first floating diffusion zone and a second floating diffusion zone that are coupled to the photovoltaic device;
a transfer transistor that is coupled between the photovoltaic device and the first floating diffusion zone; and
a dual conversion gain transistor that is coupled between the first floating diffusion zone and the second floating diffusion zone,
wherein the second floating diffusion zone includes a capacitor,
wherein the capacitor includes a first electrode and a second electrode that overlap each other, and a dielectric layer that is between the first electrode and the second electrode,
wherein the plurality of pixels include a first pixel and a second pixel adjacent to each other, and
wherein the second electrode of the first pixel and the second electrode of the second pixel are integral with each other.

14. The image sensor of claim 13, further comprising:
a first wiring line that is coupled between the photovoltaic device and the first electrode of the capacitor;
a first insulating layer that is between the first electrode of the capacitor and the first wiring line; and
a first via that extends through the first insulating layer so as to couple the first electrode of the capacitor and the first wiring line together.

15. The image sensor of claim 14, wherein the second electrode includes a first hole that overlaps the first via, and
wherein the first hole overlaps the first electrode of the capacitor.

16. The image sensor of claim 14, wherein the first electrode of the first pixel and the first electrode of the second pixel are spaced apart from each other.

17. The image sensor of claim 16, further comprising a second via that extends through the first insulating layer and the dielectric layer so as to be coupled to the first wiring line,
wherein the second electrode includes a second hole that overlaps the second via,
wherein the second hole is free of overlap in a vertical direction with the first electrode of the capacitor, and
wherein the second hole is between the first electrode of the first pixel and the first electrode of the second pixel.

18. An image sensor comprising:
a plurality of pixels, each of which comprises:
a light transmission layer;
a photoelectric conversion layer configured to convert light passing through the light transmission layer into an electrical signal;
a transfer transistor that is coupled to the photoelectric conversion layer;
a first floating diffusion zone and a dual conversion gain transistor that are coupled to the transfer transistor; and
a capacitor that is coupled to the dual conversion gain transistor,
wherein the capacitor includes a first electrode and a second electrode that overlap each other, and a dielectric layer that is between the first electrode and the second electrode,
wherein the plurality of pixels include a first pixel and a second pixel adjacent to each other, and
wherein the second electrode of the first pixel and the second electrode of the second pixel are integral with each other.

19. The image sensor of claim 18, wherein the plurality of pixels further include a third pixel and a fourth pixel adjacent to the first pixel and the second pixel, and
wherein the second electrode of the first pixel, the second electrode of the second pixel, the second electrode of the third pixel, and the second electrode of the fourth pixel are integral with each other.

20. The image sensor of claim 18, wherein the second electrodes of the plurality of pixels are integral with each other.
